(19) United States
(12) Patent Application Publication
(10) Pub. No.: US 2025/0096063 A1
(43) Pub. Date: Mar. 20, 2025

(54) SEMICONDUCTOR DEVICE

(71) Applicant: Mitsubishi Electric Corporation, Chiyoda-ku, Tokyo (JP)

(72) Inventors: Seiu HIGASHIDE, Tokyo (JP); Katsumi MIYAWAKI, Tokyo (JP); Shunichi ABE, Tokyo (JP); Takumi NAGAMINE, Tokyo (JP)

(73) Assignee: Mitsubishi Electric Corporation, Chiyoda-ku, Tokyo (JP)

(21) Appl. No.: 18/729,548

(22) PCT Filed: Feb. 3, 2023
(86) PCT No.: PCT/JP2023/003640

§ 371 Date: Jul. 17, 2024

(30) Foreign Application Priority Data
Feb. 14, 2022 (JP) 2022-020303

(51) Int. Cl. H01L 23/367; H01L 23/00; H01L 23/29; H01L 23/31

(52) U.S. Cl. CPC H01L 23/3672; H01L 23/3121; H01L 23/295; H01L 24/14; H01L 24/16; H01L 24/32; H01L 24/73; H01L 2224/14152; H01L 2224/16225; H01L 2224/32245; H01L 2224/73253; H01L 2924/35121

(57) ABSTRACT

A semiconductor device includes a semiconductor chip, a heat-dissipating plate, and a sealing resin, in which the semiconductor chip is mounted face-down on a substrate, the heat-dissipating plate is bonded to an upper surface of the semiconductor chip with a bonding material, the sealing resin seals the semiconductor chip and side surfaces of the heat-dissipating plate, an upper surface of the heat-dissipating plate is an exposed surface exposed from an upper surface of the sealing resin, a convex portion or a concave portion is provided on the side surface of the heat-dissipating plate, and at least an upper surface of the convex portion or at least a lower surface of the concave portion is in contact with the sealing resin.

### TECHNICAL FIELD

The present disclosure relates to a semiconductor device.

### BACKGROUND ART

In a semiconductor device, a semiconductor chip using a semiconductor such as Si is mounted on a wiring board. In recent years, semiconductor devices with a face-down structure, in which the circuit surface of a semiconductor chip faces a wiring board, for miniaturization thereof, have been increasing. In a semiconductor device that adopts the face-down structure, it is effective to install a heat-dissipating plate with a high thermal conductivity on a surface opposite to a circuit surface of the semiconductor chip, using adhesive or the like, in order to efficiently dissipate the heat generated in the semiconductor chip. The heat-dissipating plate effectively dissipates heat generated in the semiconductor chip to the outside of the semiconductor device by coming into contact with a casing or the air outside the semiconductor device.

Further, such a semiconductor device is typically provided with a structure in which the semiconductor chip and the heat-dissipating plate are sealed with a resin in order to prevent damage due to, such as water droplets, conductive foreign matter. Sealing with a resin is generally conducted by resin molding using a mold. At this point, if the mold and the heat-dissipating plate come into contact with each other, there is a concern that the semiconductor chip, which is bonded to the heat-dissipating plate, may be damaged, the internal dimensions of the mold are set large enough to avoid contact with the heat-dissipating plate. Therefore, at the stage where resin sealing is conducted, the heat-dissipating plate is embedded in the sealing resin. Yet, the sealing resin is a resin such as epoxy and has low thermal conductivity, which impairs the heat dissipation property of the semiconductor device. Therefore, it is necessary to increase the heat dissipation property of the semiconductor device by somehow exposing the embedded heat-dissipating plate from the sealing resin.

### PRIOR ART DOCUMENTS

### Patent Document(s)

[Patent Document 1] Japanese Patent Application Laid-Open No. 2005-136323

### SUMMARY

### Problem to be Solved by the Invention

Both tools and a heat-dissipating plate used for cutting, polishing, and the like have inclinations and distortions. After performing resin molding, when partially removing the resin by cutting or polishing to expose the heat-dissipating plate from the resin, if cutting or polishing is halted right at the instant when a portion of the heat-dissipating plate is exposed, some portion of the surface of the heat-dissipating plate that should be exposed remains covered with the sealing resin. Therefore, in order to completely expose one full surface of the heat-dissipating plate from the sealing resin, it is necessary to continue cutting or polishing even after the heat-dissipating plate begins to be exposed. At this point, a tool used for cutting, polishing, or the like comes into contact with an end portion or a corner of the heat-dissipating plate, generating stress on the heat-dissipating plate in a direction that causes the heat-dissipating plate to peel away from the semiconductor chip. When a bonding surface between the heat-dissipating plate and the semiconductor chip is peeled off due to the stress, thermal conduction from the semiconductor chip to the heat-dissipating plate is inhibited, lowering the heat dissipation property of the semiconductor device.

The present disclosure has been made to solve the above-mentioned problems, and an object thereof is to provide a semiconductor device in which, even when a process of exposing the heat-dissipating plate embedded in the sealing resin during manufacturing, peeling off caused the bonding surface between the semiconductor chip and the heat-dissipating plate can be suppressed, thereby suppressing a decrease in heat dissipation property.

### Means to Solve the Problem

A semiconductor device of the present disclosure includes a substrate, a semiconductor chip, a heat-dissipating plate, and a sealing resin, in which the semiconductor chip is mounted face-down on the substrate, the heat-dissipating plate is bonded to an upper surface of the semiconductor chip with a bonding material, the sealing resin seals the semiconductor chip and side surfaces of the heat-dissipating plate, an upper surface of the heat-dissipating plate is an exposed surface exposed from an upper surface of the sealing resin, a convex portion is provided on the side surface of the heat-dissipating plate, the convex portion is a portion that protrudes from an outer periphery of the exposed surface in a direction in which the side surface faces, the convex portion is in contact with the sealing resin, the convex portion is bonded to the upper surface of the semiconductor chip with the bonding material, and external dimensions of the heat-dissipating plate having the side surface provided with the convex portion in plan view are smaller than external dimensions of the semiconductor chip in plan view.

### Effects of the Invention

According to the present disclosure, a semiconductor device is provided in which, even when a process of exposing the heat-dissipating plate embedded in the sealing resin during manufacturing, peeling off caused the bonding surface between the semiconductor chip and the heat-dissipating plate can be suppressed, thereby suppressing a decrease in heat dissipation property.

The objects, characteristics, aspects, and advantages of the technique disclosed in the present specification will become more apparent from the following detailed description and the accompanying drawings.

### BRIEF DESCRIPTION OF DRAWINGS

FIG. 1 A diagram illustrating an example of a semiconductor device of Embodiment 1.

FIG. 2 A cross-sectional view taken along line A-A in FIG. 1 of an example of the semiconductor device of Embodiment 1.

FIG. 3 A diagram illustrating an other example of a semiconductor device of Embodiment 1.

FIG. 4 A cross-sectional view taken along line B-B in FIG. 1 of an other example of the semiconductor device of Embodiment 3.

FIG. 5 A diagram illustrating a semiconductor device of Embodiment 2.

FIG. 6 A cross-sectional view taken along line C-C in FIG. 5 of the semiconductor device of Embodiment 2.

FIG. 7 A diagram illustrating a semiconductor device of Embodiment 3.

FIG. 8 A cross-sectional view taken along line D-D in FIG. 7 of the semiconductor device of Embodiment 3.

FIG. 9 A diagram illustrating a semiconductor device of Embodiment 4.

### DESCRIPTION OF EMBODIMENT(S)

In the following description, terms indicating specific directions such as “upper”, “lower” and the like, these terms are for promoting the understanding of the contents of Embodiments and are not related to the directions at the time of manufacturing or implementing the semiconductor device.

### A. Embodiment 1

### A-1. Configuration

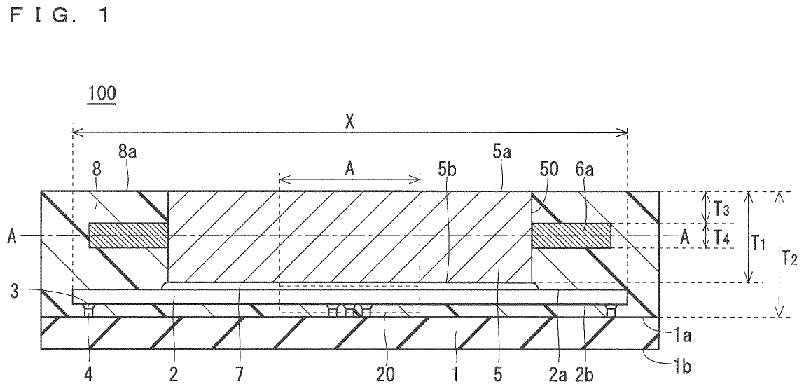

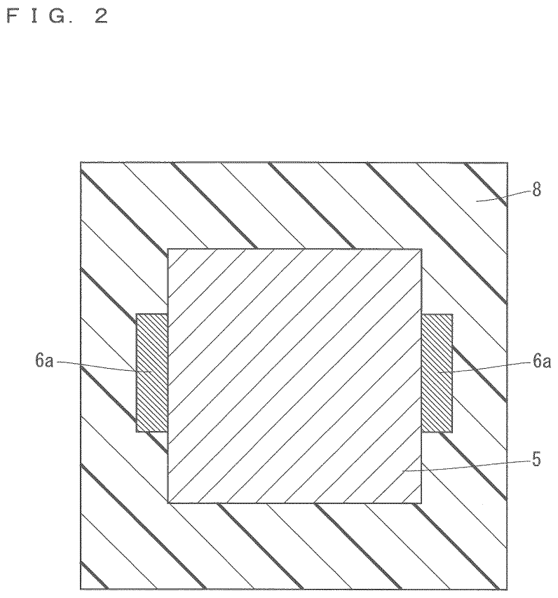

FIG. 1 is a diagram illustrating a semiconductor device 100 of Embodiment 1. FIG. 2 is a cross-sectional view taken along line A-A in FIG. 1 of the semiconductor device 100.

The semiconductor device 100 includes a substrate 1, a semiconductor chip 2, an electrode 3, a bonding portion 4, a heat-dissipating plate 5, a bonding material 7, and a sealing resin 8.

The substrate 1 has an upper surface 1a and a lower surface 1b.

The semiconductor chip 2 has an upper surface 2a and a circuit surface 2b being a lower surface 2b.

The circuit surface 2b of the semiconductor chip 2 faces the upper surface 1a of the substrate 1. In other words, the semiconductor chip 2 is mounted face-down on the substrate 1.

On the circuit surface 2b of the semiconductor chip 2, the electrode 3 is formed.

The electrode 3 and the substrate 1 are bonded via the bonding portion 4.

A heat-dissipating plate 5 is bonded to the upper surface 2a of the semiconductor chip 2 via the bonding material 7.

The upper surface of the heat-dissipating plate 5 is an exposed surface 5a exposed from an upper surface 8a of the sealing resin 8. The exposed surface 5a of the heat-dissipating plate 5 and the upper surface 8a of the sealing resin 8 are substantially flush with each other.

A side surface 50 of the heat-dissipating plate 5 is provided with a convex portion 6a. The convex portion 6a is a portion that protrudes from the outer periphery of the exposed surface 5a in the direction in which the side surface 50 faces, and is a portion that does not overlap the exposed surface 5a in plan view.

The sealing resin 8 seals the semiconductor chip 2, the bonding portion 4, the electrode 3, the bonding material 7, the convex portions 6a, the upper surface 1a of the substrate 1, and the side surfaces 50 of the heat-dissipating plate 5. That is, the sealing resin 8 is in contact with at least the upper surface of the convex portion 6a.

Hereinafter, each element comprising the semiconductor device 100 will be described in more detail below.

The substrate 1 may be a wiring board made of a typical insulator as a base material. The base material of the substrate 1 requires insulation and heat resistance. The base material of the substrate 1 is, for example, a paper phenol base material or a glass epoxy base material in which glass fiber is impregnated with epoxy resin. When the frequency of the electrical signal applied to the semiconductor device 100 exceeds 1 GHz, a material with lower dielectric loss is preferable to adopt. Such materials with lower dielectric loss are, for example, glass substrates or ceramic substrates such as alumina. If the semiconductor device 100 is to have flexibility, a flexible printed circuit board using polyimide resin or various polymers may be used as the substrate 1.

A circuit pattern required for the operation of the semiconductor device 100 is formed on the front surface of the substrate 1. The circuit pattern is formed of a conductor. The conductor is a conductor with high conductivity and processability, for example, a metal such as aluminum, copper, nickel, gold, and silver, or an alloy thereof. The method of forming the circuit pattern may be selected from various methods such as a subtractive method or an additive method, in a manner that an appropriate method is selected depending on the circuit pattern width and the distance between the circuit patterns required for the semiconductor chip 2. The subtractive method is a method of forming a circuit pattern by removing unnecessary portions other than the circuit pattern from a copper-clad laminate by etching or the like. The additive method is a method of forming a circuit pattern by laminating a conductor required for the circuit pattern using vapor deposition, plating, or the like.

A solder resist, a positioning pattern, or the like may be formed on the upper surface la and the lower surface 1b of the substrate 1. The solder resist is used to prevent short circuits between circuits due to solder wetting and spreading. The positioning pattern is a pattern used for positioning the semiconductor chip 2 when mounting the semiconductor chip 2 on the substrate 1.

The semiconductor chip 2 is a semiconductor chip in which a planar semiconductor element is formed on the circuit surface 2b side of a semiconductor substrate. The planar semiconductor element is an active element, a passive element, or both. The material of the semiconductor substrate is Si, SiC, GaAs, GaN, or the like.

Although there are no particular limitations on the external dimensions of the semiconductor chip 2, for example, the length of one side is about 0.05 mm to 30 mm, and the thickness is about 50 um to 750 um.

On the circuit surface 2b of the semiconductor chip 2, the electrode 3 is formed. Through the electrode 3, a current can be passed from outside the semiconductor chip 2 to the circuit formed on the semiconductor chip 2.

The electrode 3 and the substrate 1 are bonded via the bonding portion 4. In FIG. 1, although five electrodes 3 and five bonding portions 4 are illustrated as an example, any number of electrodes 3 and bonding portions 4 may be provided depending on the functions required for the semiconductor chip 2. Furthermore, the electrodes 3 and the bonding portions 4 may be provided at arbitrary positions depending on the functions required for the semiconductor chip 2.

A ground conductor layer may be provided on the upper surface 2a of the semiconductor chip 2. Specifically, the ground conductor is, for example, copper, aluminum, gold plated, or the like.

The material of the electrode 3 is, for example, a highly conductive metal material such as copper or aluminum. The front surface of the electrode 3 may be plated with nickel or gold to prevent oxidation or corrosion. The electrode 3 may be formed by an additive method using plating, vapor deposition, sputtering, or the like, or by a subtractive method using etching or the like.

The material of the bonding portion 4 is, for example, a highly conductive metal material such as gold, silver, copper, aluminum, tin, or the like. The bonding portion 4 serves to electrically connect the substrate 1 and the electrode 3. Further, it is desirable that the thickness of the bonding portion 4 is three times or more the maximum diameter of a filler contained in the sealing resin 8, which will be described later. During manufacturing, the bonding portion 4 may be attached to either the electrode 3 or the substrate 1 in advance before the process of bonding the electrode 3 and the substrate 1 to each other, or may be supplied in the process of bonding the electrode 3 and the substrate 1 to each other.

Examples of methods of bonding the bonding portion 4, the electrode 3 and the substrate 1 to one another include, for example, a metal diffusion bonding method in which bonding thereof is performed by applying heat, pressure, and ultrasonic waves, a method in which bonding thereof is performed by soldering or brazing, a method in which bonding thereof is performed by adhesion using an adhesive with conductivity, and the like.

The material of the heat-dissipating plate 5 is preferably a material with high thermal conductivity. The material of the heat-dissipating plate 5 is, for example, a metal, a ceramic material, a carbon-containing material, or a composite material made by combining these materials in an arbitrary ratio. The metal used as the material for the heat-dissipating plate 5 is, for example, gold, silver, copper, aluminum, tungsten, molybdenum, or the like. The ceramic material used as the material for the heat-dissipating plate 5 is, for example, aluminum nitride, boron nitride, or the like. The carbon-containing material used as the material for the heat-dissipating plate 5 is, for example, graphite, graphene, diamond, or the like.

The dimensions of the heat-dissipating plate 5 are designed to effectively dissipate heat generated by the semiconductor chip.

When the semiconductor chip 2 generates heat in the entire area in the in-plane direction, it is desirable that the external dimensions of the semiconductor chip 2 in plan view are a rectangle of X mm×Y mm (only X is illustrated in FIG. 1), and the external dimensions of the heat-dissipating plate 5 in plan view are (X+2T₁)mm×(Y+2T₁) mm or more, wherein T₁ represents the thickness of the heat-dissipating plate 5. Further, it is desirable that the semiconductor chip 2 be placed in the center of the heat-dissipating plate 5 in plan view.

When the semiconductor chip 2 generates heat intensively in a certain region (for example, a region 20 in FIG. 1) in the in-plane direction, the dimensions of the heat-dissipating plate 5 may be designed based on the external dimensions of the heat-generating area. In other words, when the external dimensions of the heat-generating area on the circuit surface of the semiconductor chip 2 are a rectangle of A mm×B mm (only A is illustrated in FIG. 1), the external dimensions of the heat-dissipating plate 5 are desirably (A+2T mm)×(B+2T mm) or more. Further, it is desirable that the region 20 be arranged at the center of the heat-dissipating plate 5 in plan view. FIG. 1 illustrates the semiconductor device 100 in which the semiconductor chip 2 generates heat intensively in the region 20.

When the semiconductor chip 2 has a plurality of heat-generating areas, a plurality of heat-dissipating plates 5 may be mounted on one semiconductor chip 2, or one heat-dissipating plate 5 may be mounted to cover all of the plurality of heat-generating areas. In any case, the heat generated by the semiconductor chip 2 can be effectively dissipated by mounting the heat-dissipating plate 5 that satisfies the above-mentioned external dimension conditions on each heat-generating area.

The convex portions 6a are provided on the side surfaces 50 of the heat-dissipating plate 5, and the sealing resin 8 is in contact with the upper side of the convex portions 6a, so that the heat-dissipating plate 5 is supported by the sealing resin 8. Therefore, the heat-dissipating plate 5 and the semiconductor chip 2 are less likely to separate from each other when an external force is applied to the heat-dissipating plate 5.

It is preferable that the projected area of the convex portions 6a with respect to a plane along the exposed surface 5a (corresponding to the area of the densely hatched portion indicated by the symbol 6a in FIG. 2) is 10% or more of the area of the exposed surface 5a of the heat-dissipating plate 5 (corresponding to the area of the sparsely hatched portion indicated by the symbol 5 in FIG. 2). The large projected area of the convex portions 6a with respect to the plane along the exposed surface 5a increases the effectiveness of supporting the heat-dissipating plate 5 with the sealing resin 8.

Although it is desirable that the material of the convex portion 6a is the same as that of the portion of the heat-dissipating plate 5 other than the convex portions 6a, the material of the convex portion 6a may differ from the material of the portion of the heat-dissipating plate 5 other than the convex portions 6a.

The shape of the convex portion 6a is not particularly limited. For example, the convex portion 6a may have a square prism shape with the side surface 50 of the heat-dissipating plate 5 as the bottom surface, or may have a triangular pyramid shape with the side surface 50 of the heat-dissipating plate 5 as the bottom surface.

The thickness T₄ of the convex portion 6a is preferably 10% or more of the thickness T₁ of the heat-dissipating plate 5. The thicker the convex portion 6a is, the higher the strength of the convex portion 6a becomes. When the thickness of the convex portion 6a varies depending on the position in the in-plane direction, the thickness of the thickest portion at the root of the convex portion 6a, that is, the portion that overlaps the outline of the exposed surface 5a in plan view, need only be equal to or more than 10% of the thickness T₁ of the heat-dissipating plate 5.

The distance T₃ in the thickness direction between the upper surface 8a of the sealing resin 8 and the upper surface of the convex portion 6a is preferably 10% or more of the thickness T₂ of the sealing resin 8. The larger T₃ is, the higher the strength of the portion of the sealing resin 8 that is in contact with the convex portions 6a from above becomes. When the distance in the thickness direction between the upper surface 8a of the sealing resin 8 and the upper surface of the convex portion 6a varies depending on the in-plane position, the distance need only be equal to or more than 10% of the thickness T₂ of the sealing resin 8 at the location where the distance in the thickness direction between the upper surface 8a of the sealing resin 8 and the upper surface of the convex portion 6a is the largest.

The convex portion 6a is located further inside the semiconductor device 100 than the side surface of the sealing resin 8. That is, the convex portion 6a does not reach the side surface of the sealing resin 8 and is not exposed from the side surface of the sealing resin 8.

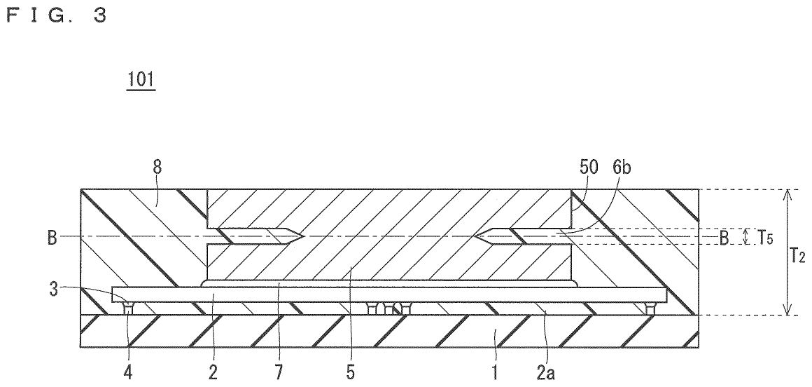

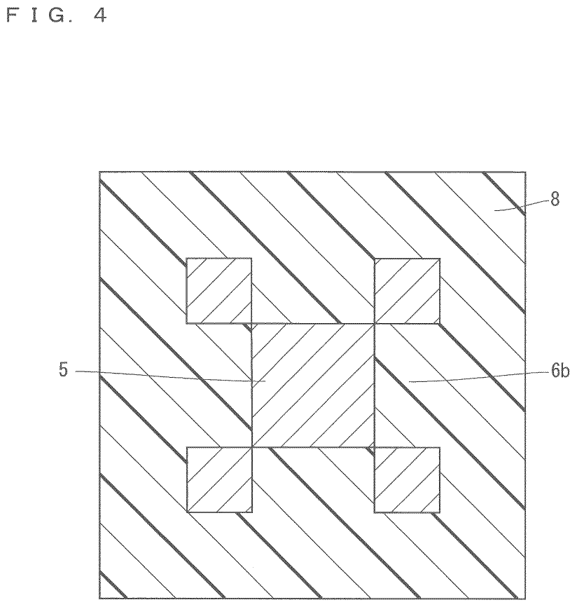

FIG. 3 is a diagram illustrating a semiconductor device 101 that is a modification of the semiconductor device 100 of Embodiment 1. FIG. 4 is a cross-sectional view taken along line B-B in FIG. 3 of the semiconductor device 101.

The semiconductor device 101 differs from the semiconductor device 100 in that a concave portion 6b is provided on the side surface 50 of the heat-dissipating plate 5 instead of the convex portion 6a. The semiconductor device 101 is similar to the semiconductor device 100 in other respects.

The concave portion 6b is a portion that is vertically sandwiched in the heat-dissipating plate 5 and is concaved from the outer periphery of the exposed surface 5a in a direction opposite to the direction in which the side surface 50 faces. The sealing resin 8 seals the heat-dissipating plate 5 in the concave portions 6b. In other words, at least the lower surfaces of the concave portions 6b are in contact with the sealing resin 8.

It is preferable that the thickness T₅ of the concave portion 6b is 10% or more of the thickness T₂ of the sealing resin 8. The thicker the concave portion 6b is, the higher the strength of the portion of the sealing resin 8 located within the concave portion 6b becomes. When the thickness of the concave portion 6b varies depending on the position in the in-plane direction, the thickness of the thickest portion at the root of the concave portion 6b, that is, the portion that overlaps the outline of the exposed surface 5a in plan view, need only be equal to or more than 10% of the thickness T₂ of the sealing resin 8.

The bottom surface of the concave portion 6b, that is, the inner end portion in plan view, is preferably located outside the center of the heat-dissipating plate 5.

The shape of the concave portion 6b is not particularly limited. For example, the concave portion 6b may have a square prism shape with the side surface 50 of the heat-dissipating plate 5 as the bottom surface, or may have a triangular pyramid shape with the side surface 50 of the heat-dissipating plate 5 as the bottom surface.

FIG. 2 illustrates a case where the convex portions 6a are provided at two places on the side surfaces of the heat-dissipating plate 5, and FIG. 4 illustrates a case where the concave portions 6b are provided at four places on the side surfaces of the heat-dissipating plate 5. However, any number of the convex portions 6a or the concave portions 6b may be provided at any location depending on the required function.

The convex portion 6a or the concave portion 6b can be formed by scraping off the heat-dissipating plate 5 by cutting, grinding, polishing, etching, laser machining, or the like. Further, the convex portion 6a or the concave portion 6b can also be formed by adding a side surface structure to the heat-dissipating plate 5 by a method such as plating or vapor deposition. Regardless of the method, it is preferable that the convex portions 6a and the concave portions 6b are formed so that the heat-dissipating plate 5 and the convex portions 6, or the portion of the heat-dissipating plate 5 around the concave portions 6b and the other portion of the heat-dissipating plate 5, are firmly attached to each other so as not to separate.

The bonding material 7 is desirably a bonding material that can bond well to the surfaces of both the semiconductor chip 2 and the heat-dissipating plate 5. It is desirable that the bonding material 7 has high thermal conductivity. The bonding material 7 is, for example, a silver sintered material, a conductive adhesive, solder, or the like.

The silver sintered material used as the bonding material 7 is, for example, one in which silver particles of approximately several nanometers are dispersed in a small amount of solvent. The silver sintered material used as the bonding material 7 is desirably a material that is sintered at a temperature lower than the heat resistant temperature of the semiconductor chip 2. For example, when the material of the semiconductor chip 2 is Si, the sintering temperature of the bonding material 7 is desirably 300° C. or lower, more desirably 200° C. or lower.

The conductive adhesive used as the bonding material 7 is, for example, a conductive adhesive made by mixing conductive particles such as silver, copper, gold, nickel, or the like, into a resin such as epoxy resin, acrylic resin, silicone resin, or the like. The conductive particles may be resin particles whose surfaces are coated with a metal such as silver, copper, gold, nickel, or the like, by plating or vapor deposition. The conductive adhesive used as the bonding material 7 may be either a one-component type or a two-component mixture type of conductive adhesive, and may also be any type of the conductive adhesive from various types such as a thermosetting type, a moisture curing type, an ultraviolet curing type, and the like.

The solder used as the bonding material 7 is, for example, a eutectic solder containing 38% lead by weight in addition to tin, a lead-free solder containing 3% silver by weight and 0.5% copper by weight in addition to tin, or solder containing 80% gold by weight in addition to tin. In either case, the bonding material 7 is solder that can be soldered at a temperature below the heat resistant temperatures of the substrate 1 and the semiconductor chip 2.

The bonding material 7 desirably has a viscosity that allows easy adjustment of the amount of application and does not flow out from the area of application. The viscosity of the bonding material 7 is, for example, 10 Pa·s to 100 Pa·s, desirably 20 Pa·s to 50 Pa·s.

The amount of the bonding material 7 to be applied is desirably such that a fillet is formed on the side surfaces of the semiconductor chip 2 or the heat-dissipating plate 5, which has the smaller area in plan view and is in contact with the bonding material 7. Methods for applying the bonding material 7 include an air dispenser, a constant volume screw dispenser, pin transfer, printing supply, and the like.

The sealing resin 8 is, for example, epoxy resin or silicone resin. Fine particles such as silica or boron nitride may be mixed into the sealing resin 8 in order to improve heat dissipation or adjust the thermal expansion coefficient.

The sealing resin 8 seals the components from the upper surface 1a of the substrate 1 to the exposed surface 5a of the heat-dissipating plate 5 except for the exposed surface 5a. The external dimensions of the sealing resin 8 in plan view are equivalent to the external dimensions of the substrate 1, and the thickness T₂ of the sealing resin 8 is equal to the total thickness of the bonding portions 4, the electrode 3, the semiconductor chip 2, the bonding material 7, and the heat-dissipating plate 5.

### A-2. Method of Manufacturing

First, the substrate 1 and the semiconductor chip 2 are bonded face down.

Next, the bonding material 7 is applied to the upper surface 2a of the semiconductor chip 2.

Next, using equipment with high mounting position accuracy such as an automatic mounter or a die bonder, the heat-dissipating plate 5 picked up by a vacuum suction nozzle is mounted on the upper surface 2a of the semiconductor chip 2 applied with the bonding material 7.

Next, in order to bond the semiconductor chip 2 and the heat-dissipating plate 5 to each other, a reflow process or a curing process suitable for each bonding material 7 is performed.

Next, seal with sealing resin 8 so that, from the surface of substrate 1 to all five surfaces excluding the surface of the heat-dissipating plate 5 at which the semiconductor chip 2 is bonded. As for the sealing method, use a transfer method is desirable that enables to fill a minute gap, which is the gap that is minute between the substrate 1 and the semiconductor chip 2.

After the sealing resin 8 is cured, the sealing resin 8 and the substrate 1 are diced to divide into individual pieces.

Next, the upper surface of the sealing resin 8 is ground to expose the heat-dissipating plate 5 from the sealing resin 8.

Through the above processes, the semiconductor device 100 or the semiconductor device 101 is manufactured. The above processes can be rearranged in order thereof as necessary.

The projected area of the convex portions 6a or the concave portions 6b projected onto a plane along the exposed surface 5a being 10% or more of the area of the exposed surface 5a brings the convex portions 6a or the concave portions 6b and the sealing resin 8 in a state where they are engaged with one another with the corrugated bonding surfaces as illustrated in FIG. 1 or FIG. 3, and are firmly fixed.

### A-3. Function

The projected area of the convex portions 6a or the concave portions 6b with respect to the plane along the exposed surface 5a is, for example, 10% or more of the area of the exposed surface 5a. With such a configuration, the sealing resin 8 and the convex portions 6a or the concave portions 6b are in a state where they are engaged with the corrugated bonding surfaces as illustrated in FIG. 1 or FIG. 3, and are firmly fixed.

In the semiconductor device 100, the thickness T₄ of the convex portion 6a is preferably 10% or more of the thickness T₁ of the heat-dissipating plate 5. Thereby, the convex portion 6a has high strength.

In the semiconductor device 100, the distance T₃ from the upper surface 8a of the sealing resin 8 to the upper surface of the convex portion 6a is, for example, 10% or more of the thickness T₂ of the sealing resin 8. Thereby, the sealing resin 8 above the convex portions 6a has high strength.

In the semiconductor device 101, the thickness T₅ of the concave portion 6b is, for example, 10% or more of the thickness T₂ of the sealing resin 8. With such a configuration, the sealing resin 8 inside the concave portions 6b has high strength, thereby firmly fixing the heat-dissipating plate 5 by the sealing resin 8.

In the process of exposing the heat-dissipating plate 5 from the sealing resin 8, even if a tool used for grinding comes into contact with the end portion or the corner portion of the heat-dissipating plate 5, which generates stress on the heat-dissipating plate 5 in the direction of peeling it off from the semiconductor chip 2, peeling is less likely to occur on the bonding surface between the heat-dissipating plate 5 and the semiconductor chip 2 because the sealing resin 8 and the heat-dissipating plate 5 are firmly fixed with the convex portions 6a or the concave portions 6b being provided. Thereby, a semiconductor device with high heat dissipation property can be provided.

### A-4. Effect

With the convex portions 6a or the concave portions 6b being provided, in the semiconductor device 100 or the semiconductor device 101, the sealing resin 8 and the heat-dissipating plate 5 are firmly fixed; therefore, even if a process such as cutting or polishing that exposes the heat-dissipating plate 5 embedded in the sealing resin 8 is applied, peeling, that occurs at the bonding surface between the semiconductor chip 2 and the heat-dissipating plate 5, is suppressed, thereby suppressing a decrease in heat dissipation property.

### B. Embodiment 2

### B-1. Configuration

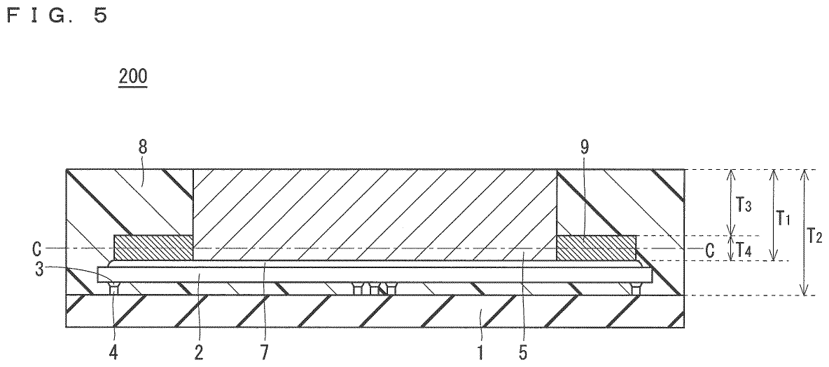

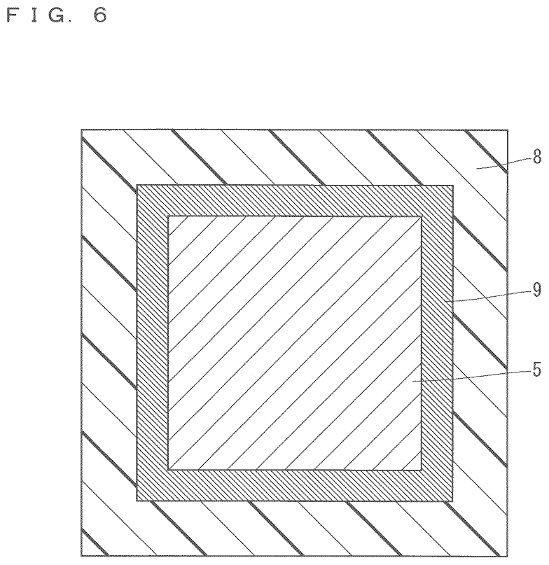

FIG. 5 is a diagram illustrating a semiconductor device 200 of Embodiment 2. FIG. 6 is a cross-sectional view taken along line C-C in FIG. 5 of the semiconductor device 200.

The semiconductor device 200 differs from the semiconductor device 100 of Embodiment 1 in that a convex portion 9 is provided on the side surface 50 of the heat-dissipating plate 5 instead of the convex portion 6a. The convex portion 9 and the semiconductor chip 2 are bonded via the bonding material 7. Thereby, the semiconductor chip 2 can be cooled more effectively. As in the case of the semiconductor device 100 of Embodiment 1, the heat-dissipating plate 5 is firmly fixed to the sealing resin 8 by the convex portion 9.

The convex portion 9 does not reach the side surface of the sealing resin 8 and is not exposed from the side surface of the sealing resin 8.

The size of the convex portion 9 need only be within a range that does not affects any design problems with the distance between the convex portion 9 and the side surface of the sealing resin 8 or the positional relationship between the convex portion 9 and the semiconductor chip 2.

The thickness T₄ of the convex portion 9 is preferably 10% or more of the thickness T₁ of the heat-dissipating plate 5. The distance T₃ between the upper surface 8a of the sealing resin 8 and the upper surface of the convex portion 9 is preferably 10% or more of the thickness T₂ of the sealing resin 8. The projected area of the convex portion 9 with respect to a plane along the exposed surface 5a is preferably 10% or more of the area of the exposed surface 5a. The material of the convex portion 9 is desirably the same as the material of the heat-dissipating plate 5.

The convex portion 9 can be formed in the same manner as the convex portion 6a in the semiconductor device 100. It is desirable to form the convex portion 9 so that the convex portion 9 and the heat-dissipating plate 5 are firmly attached to each other so that they do not part.

The semiconductor device 200 can be manufactured by a method similar to the method of manufacturing the semiconductor device 100 of Embodiment 1.

### B-2. Function

The semiconductor device 200 has the same functions as those described in <A-3. Function> for the semiconductor device 100. Therefore, the heat-dissipating plate 5 is firmly fixed to the sealing resin 8.

### B-3. Effect

With the convex portion 9 being provided on the side surface of the semiconductor device 200, in the semiconductor device 200, as in the case of the semiconductor device 100 of Embodiment 1, even if a grinding process is performed to expose the heat-dissipating plate 5 embedded in the sealing resin 8, peeling, that occurs at the bonding surface between the semiconductor chip 2 and the heat-dissipating plate 5, is suppressed, thereby suppressing a decrease in heat dissipation property.

The convex portion 9 is in contact with the semiconductor chip 2 via the bonding material 7; therefore, the heat of the semiconductor chip 2 can be dissipated more effectively. Thereby, a semiconductor device with higher heat dissipation property can be provided.

### C. Embodiment 3

### C-1. Configuration

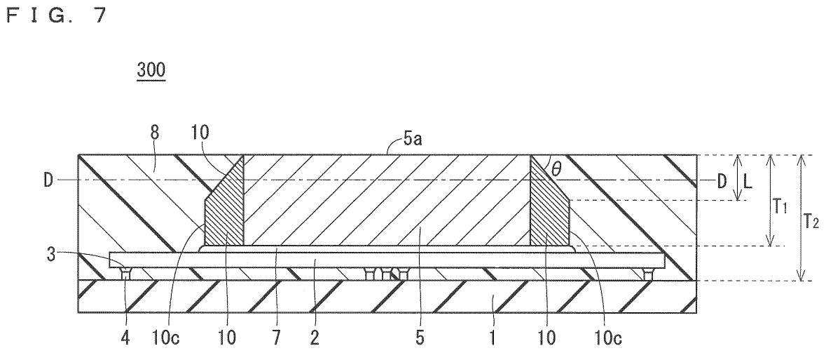

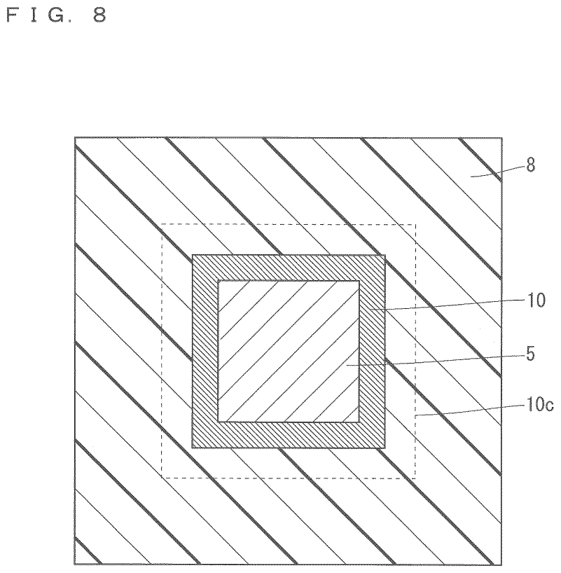

FIG. 7 is a cross-sectional view of a semiconductor device 300 of Embodiment 3. FIG. 8 is a cross-sectional view taken along line D-D in FIG. 7 of the semiconductor device 300.

The semiconductor device 300 differs from the semiconductor device 100 in that a convex portion 10 is provided on the side surface of the heat-dissipating plate 5 instead of the convex portion 6a.

In FIG. 8, an outer periphery 10c (see FIG. 7) of the convex portion 10 is indicated by a broken line. The outer periphery 10c of the convex portion 10 does not reach the side surface of the sealing resin 8 and is not exposed from the side surface of the sealing resin 8. The convex portion 10 is provided on the side surfaces of the heat-dissipating plate 5 over the entire area in the thickness direction.

The convex portion 10 has a tapered shape in which the tip end thereof positioned at the exposed surface 5a of the heat-dissipating plate 5 and it widens in the in-plane direction as it is away from the exposed surface 5a. An angle θ (see FIG. 7) between the front surface of the tapered shape portion and the exposed surface 5a is greater than 0° and smaller than 90°. In order to obtain the effect of more firmly fixing the heat-dissipating plate 5 via the convex portion 10 by the sealing resin 8, it is preferable that the angle θ is not too large. The angle θ is, for example, 45° or less.

A width L in the thickness direction of the tapered shape portion of the convex portion 10 (see FIG. 7) is preferably larger than 1/100 of the thickness T1 of the heat-dissipating plate 5 and smaller than ½ of the same. Further, the width L of the tapered shape portion of the convex portion 10 in the thickness direction is, for example, 10% or more of the thickness T₂ of the sealing resin 8. The larger the width L in the thickness direction of the tapered shape portion of the convex portion 10 is, the higher the strength of the sealing resin 8 that supports the tapered portion of the convex portion 10 becomes. The projected area of the convex portion 10 with respect to a plane along the exposed surface 5a is preferably 10% or more of the area of the exposed surface 5a. The convex portion 10 is desirably located on the exposed surface 5a side of the side surfaces of the heat-dissipating plate 5 over the entire outer periphery in plan view. However, in a case where the direction of grinding to expose the heat-dissipating plate 5 from the sealing resin 8 is determined to be one direction, the convex portion 10 may be provided only on the outer periphery where the tool comes into contact.

Methods of forming the convex portions 10 include cutting, grinding, polishing, laser processing, etching, and the like.

The semiconductor device 300 can be manufactured by a method similar to the method of manufacturing the semiconductor device 100 of Embodiment 1.

### C-2. Function

With the convex portion 10 being provided, the heat-dissipating plate 5 is firmly fixed to the sealing resin 8. Further, with the convex portion 10 being provided, the direction of stress generated when a tool comes into contact with the end portion of the heat-dissipating plate 5 during the grinding process or the like is dispersed. Therefore, peeling, that occurs at the bonding surface between the semiconductor chip 2 and the heat-dissipating plate 5, is further suppressed, thereby suppressing a decrease in heat dissipation property.

### C-3. Effect

With the convex portion 10 being provided on the side surface of the semiconductor device 300, in the semiconductor device 300, as in the case of the semiconductor device 100 of Embodiment 1, even if a grinding process is performed to expose the heat-dissipating plate 5 embedded in the sealing resin 8, peeling, that occurs at the bonding surface between the semiconductor chip 2 and the heat-dissipating plate 5, is suppressed, thereby suppressing a decrease in heat dissipation property.

With the convex portion 10 having a tapered shape with the exposed surface 5a as the tip thereof, the direction of stress generated when a tool comes into contact with the end portion of the heat-dissipating plate 5 during the grinding process or the like in which the heat-dissipating plate 5 embedded in the sealing resin 8 is exposed is changed. That is, the tool comes into contact with the tapered shape portion of the convex portion 10, thereby reducing the stress generated in the direction of peeling the heat-dissipating plate 5 and the semiconductor chip 2. Consequently, peeling that occurs at the bonding surface between the semiconductor chip 2 and the heat-dissipating plate 5 is more effectively suppressed, thereby more effectively suppressing a decrease in heat dissipation property of the semiconductor device 300.

### D. Embodiment 4

### D-1. Configuration

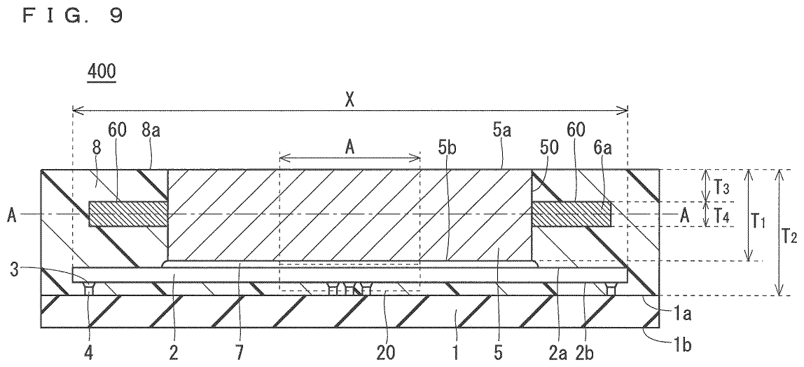

FIG. 9 is a diagram illustrating a semiconductor device 400 of Embodiment 4.

The semiconductor device 400 differs from the semiconductor device 100 of Embodiment 1 in that a region 60 is provided on the front surface of the convex portion 6a. The convex portion 6a is in contact with the sealing resin 8 in the region 60. The region 60 may include the entire area of the surface of the convex portion 6a that is in contact with the sealing resin 8, or may include a portion of the area of the surface of the convex portion 6a that is in contact with the sealing resin 8. The region 60 is a region in which minute irregularities are formed on the front surface by surface processing. With this, the sealing resin 8 fills into the minute irregularities on the region 60, tightly bonding the convex portion 6a and the sealing resin 8. With the region 60 being provided, the heat-dissipating plate 5 is firmly fixed to the sealing resin 8.

The roughness of the region 60 is represented by the arithmetic mean roughness Ra. The arithmetic mean roughness Ra of the region 60 is desirably 0.8 um or more and 25 um or less. The arithmetic mean roughness Ra in the region 60 is larger than the arithmetic mean roughness Ra in the front surface of the heat-dissipating plate 5 other than the region 60.

The shape of the minute irregularities on the front surface of the region 60 is not particularly limited. For example, it may be fluffed or hemispherical.

Examples of methods of forming minute irregularities in the region 60 include etching, plasma processing, blasting, and the like.

The semiconductor device 400 can be manufactured by a method similar to the method of manufacturing the semiconductor device 100 of Embodiment 1.

### D-2. Function

The semiconductor device 400 has the same functions as those described in <A-3. Function> for the semiconductor device 100. Further, with the region 60 being provided, the sealing resin 8 fills into minute irregularities on the region 60, thereby obtaining an anchor effect. Therefore, peeling, that occurs at the bonding surface between the semiconductor chip 2 and the heat-dissipating plate 5, is further suppressed.

### D-3. Effect

With the convex portion 6a being provided on the side surface of the semiconductor device 400, in the semiconductor device 400, as in the case of the semiconductor device 100 of Embodiment 1, even if a grinding process is performed to expose the heat-dissipating plate 5 embedded in the sealing resin 8, peeling, that occurs at the bonding surface between the semiconductor chip 2 and the heat-dissipating plate 5, is suppressed. With the region 60, where the minute irregularities are formed, provided on the front surface of the convex portion 6a, the heat-dissipating plate 5 and the sealing resin 8 are more firmly fixed to each other. Consequently, peeling that occurs at the bonding surface between the semiconductor chip 2 and the heat-dissipating plate 5 is more effectively suppressed.

It should be noted that Embodiments can be arbitrarily combined and can be appropriately modified or omitted.

### EXPLANATION OF REFERENCE SIGNS

1 substrate, 1a upper surface, 1b lower surface, 2 semiconductor chip, 2a upper surface, 2b circuit surface, 3 electrode, 4 bonded portion, 5 heat-dissipating plate, 5a exposed surface, 6a, 9, 10 convex portion, 6b concave portion, 7 bonding material, 8 sealing resin, 8a upper surface, 10c outer periphery, 20, 60 region, 50 side surface, 100, 101, 200, 300, 400 semiconductor device.

1. A semiconductor device comprising:
a substrate;
a semiconductor chip;
a heat-dissipating plate; and
a sealing resin, wherein
the semiconductor chip is mounted face-down on the substrate,
the heat-dissipating plate is bonded to an upper surface of the semiconductor chip with a bonding material,
the sealing resin seals the semiconductor chip and side surfaces of the heat-dissipating plate,
an upper surface of the heat-dissipating plate is an exposed surface exposed from an upper surface of the sealing resin,
a convex portion is provided on the side surface of the heat-dissipating plate,
the convex portion is a portion that protrudes from an outer periphery of the exposed surface in a direction in which the side surface faces,
the convex portion is in contact with the sealing resin,
the convex portion is bonded to the upper surface of the semiconductor chip with the bonding material, and
external dimensions of the heat-dissipating plate having the side surface provided with the convex portion in plan view are smaller than external dimensions of the semiconductor chip in plan view.

2. The semiconductor device according to claim 1, wherein
external dimensions of the heat-dissipating plate in plan view are greater than external dimensions of a heat-generating area of the semiconductor chip in plan view.

3. The semiconductor device according to claim 1, wherein
a projected area of the convex portion projected onto a plane along the exposed surface is 10% or more of an area of the exposed surface.

4. (canceled)

5. The semiconductor device according to claim 1, wherein
a thickness of the convex portion is 10% or more of a thickness of the heat-dissipating plate.

6. The semiconductor device according to claim 1, wherein
a distance in a thickness direction between the upper surface of the sealing resin and the upper surface of the convex portion is 10% or more of a thickness of the sealing resin.

7. The semiconductor device according to claim 1, wherein
the convex portion has a tapered shape in which a tip end thereof positioned at the exposed surface of the heat-dissipating plate and it widens as it is away from the exposed surface.

8. The semiconductor device according to claim 7, wherein
an angle between the exposed surface and a front surface of the tapered shape portion is 45° or less.

9. (canceled)

10. The semiconductor device according to claim 1, wherein
an upper surface of the convex portion has a region,
the convex portion is in contact with the sealing resin in the region, and
an arithmetic mean roughness in the region is larger than an arithmetic mean roughness in a front surface of the heat-dissipating plate other than the region.

11. The semiconductor device according to claim 1, wherein
an upper surface of the convex portion has a region,
the convex portion is in contact with the sealing resin in the region, and
the arithmetic mean roughness of the region is 0.8 μm or more and 25 μm or less.

12. (canceled)

13. (canceled)

14. The semiconductor device according to claim 1, wherein
the exposed surface is flush with the upper surface of the sealing resin.
